(19) United States
(12) Patent Application Publication
(10) Pub. No.: US 2015/0021633 A1
(43) Pub. Date: Jan. 22, 2015

(54) LIGHT-EMITTING DIODE PACKAGE AND LIGHT-EMITTING DEVICE

(71) Applicant: LEXTAR ELECTRONICS CORPORATION, HSINCHU (TW)

(72) Inventor: Zong-Han YU, Keelung City (TW)

(73) Assignee: LEXTAR ELECTRONICS CORPORATION, HSINCHU (TW)

(21) Appl. No.: 14/243,844

(22) Filed: Apr. 2, 2014

(30) Foreign Application Priority Data
Jul. 17, 2013 (TW) 102125498

(51) Int. Cl. H01L 33/64; H01L 27/15

(52) U.S. Cl. CPC H01L 33/64; H01L 27/153
USPC 257/88; 257/99; 257/98

(57) ABSTRACT

An LED package is disclosed, which includes a heat dissipation plate, a composite structure, an LED chip, and an encapsulant. The heat dissipation plate has a chip bonding area, a circuit area, and a first dam disposed at the boundary between the chip bonding area and the circuit area, wherein the first dam is formed by punching or bending the heat dissipation plate. The composite structure is disposed on the circuit area. The LED chip which is disposed on the chip bonding area is electrically connected to the composite structure and covered by the encapsulant. Also a light-emitting device using the LED package is disclosed.

### CROSS REFERENCE TO RELATED APPLICATIONS

This application claims priority of Taiwan Patent Application No. 102125498, filed on Jul. 17, 2013, and the entirety of the above-mentioned patent application is incorporated by reference herein.

### BACKGROUND OF THE INVENTION

1. Field of the Invention

The invention relates to an LED (light-emitting diode) package, and in particular to an LED package in which an LED chip and a composition structure are separated by a heat-dissipation plate.

2. Description of the Related Art

An LED is one of the semiconductor devices, and an LED chip is mainly made of compounds of groups III-V, for example, gallium phosphide (GaP), gallium arsenide (GaAs) or other semiconductor compounds. The LED functions to emit light by converting electrical energy into light. In more detail, when a current is applied to the LED, the electrons and the holes in the LED are recombined for releasing photons so as to emit light. Due to the nature of the LED, the LED has a long life span of over a hundred thousand hours, and no idling time is needed to start operation. The LED has many advantages, such as fast response speed (about 10⁻9 seconds), small size, power-saving attributes, low pollution, high reliability, and suitability for mass production. Therefore, the LED is widely used in various fields, for example, light sources used in mega-size display boards, traffic lights, handset, scanners, fax machines, and illumination devices. In addition, since the light-emitting luminance and the light-emitting efficiency of the LED have been steadily enhanced, white LEDs are now capable of being successfully mass-produced now. Therefore, the LED is used for display or illumination applications.

Referring to FIG. 1, a conventional LED package 100 includes a substrate 110, a composition structure 120, a number of LED chips 130, and an encapsulant 140. The composition structure 120 is positioned on the substrate 110 and includes an adhesive layer 121, a dielectric layer 122, and a circuit layer 123. The LED chips 130 are positioned on the substrate 110 and connected to the circuit layer 123 by gold wire 125. The LED chips 130 and a portion of the composition structure 120 are covered by the encapsulant 140. The other portion of the composition structure 120 is exposed out of the encapsulant 140 and serves as an external electrode.

However, in a high-temperature and high-humidity environment, and projecting a high-intensity light, degradation of the composition structure 120 of the LED package 100 is significant, and the life span and luminous brightness of the LED package 100 are reduced.

### BRIEF SUMMARY OF THE INVENTION

To overcome the drawbacks in the prior art, a number of embodiments are provided by the disclosure.

According to one embodiment of the disclosure, an LED package includes a heat dissipation plate, a composite structure, an LED chip, and an encapsulant. The heat dissipation plate has a chip bonding area, a circuit area, and a first dam separating the chip bonding area and the circuit area. The first dam is formed by punching or bending the heat dissipation plate. The composition structure is disposed on the heat dissipation plate. The LED chip is disposed in the chip bonding area. The LED chip is electrically connected to the composition structure and is covered by the encapsulant.

In the above-mentioned embodiments, the LED package includes a number of LED chips disposed in the chip bonding area, and each two of the neighboring LED chips are separated from each other by a second dam. The height of the second dam is equal to or greater than the height of each LED chip. The second dam is formed by punching or bending a portion of the heat dissipation plate corresponding to the chip bonding area. An angle θ₂ is formed between a side wall of each depressed chip bonding sub-area and the surface of the corresponding depressed chip bonding sub-area, and the angle θ₂ is greater than 90 degrees and less than 180 degrees.

According to another embodiment of the disclosure, an LED package includes a heat dissipation plate, a composite structure, a number of LED chips, and an encapsulant. The heat dissipation plate has a chip bonding area, a circuit area, and a first dam separating the chip bonding area and the circuit area. The chip bonding area has a plurality of depressed chip bonding sub-areas formed by punching. The composition structure is disposed on the circuit area. The LED chips are respectively disposed in one of the depressed chip bonding sub-areas. The LED chips are electrically connected to the composition structure and covered by the encapsulant.

In the above-mentioned embodiments, each of the depressed chip bonding sub-areas is a circular recess or a rectangular recess. In addition, the depth of each chip bonding sub-area is equal to or greater than the height of each LED chips. Moreover, an angle θ₂ is formed between a side wall of each depressed chip bonding sub-area and the surface of the corresponding depressed chip bonding sub-area, and the angle θ₂ is greater than 90 degrees and less than 180 degrees.

In the above-mentioned embodiments, the first dam has an outer wall facing the circuit area and an inner wall facing the chip bonding area. The outer wall is perpendicular to the circuit area of the heat dissipation plate. An angle θ₁ is formed between the inner wall and the chip bonding area of the heat dissipation plate, and the angle θ₁ is greater than 90 degrees and less than 180 degrees. In addition, the top end of the first dam is as high as the surface of the composition structure.

In the above-mentioned embodiments, the LED package includes a reflective layer formed on the surface of the chip bonding area, so that the LED chip(s) is fixed on the reflective layer. In addition, the heat dissipation plate includes a metal with high heat dissipation efficiency, and the thickness of the heat dissipation plate ranges from about 0.1 mm to about 1.5 mm. Moreover, the composition structure includes a pressing layer, a dielectric layer, and a circuit layer successively stacked on the circuit area of the heat dissipation plate.

According to yet another embodiment of the disclosure, a light-emitting element including the LED package of any of the above-mentioned embodiments is also provided.

### BRIEF DESCRIPTION OF THE DRAWINGS

The invention can be more fully understood by reading the subsequent detailed description and examples with references made to the accompanying drawings.

FIG. 1 shows a cross-sectional view of an LED package in the prior art.

FIG. 2 shows a cross-sectional view of a light-emitting element, in accordance with one embodiment of the disclosure.

FIG. 3 shows a top view of an LED package of the light-emitting element of FIG. 2.

FIG. 4 shows a top view of an LED package, in accordance with another embodiment.

FIG. 5 shows a cross-sectional view of a light-emitting element, in accordance with yet another embodiment of the disclosure.

FIG. 6 shows a top view of an LED package of the light-emitting element of FIG. 5.

FIG. 7 shows a top view of an LED package, in accordance with yet another embodiment.

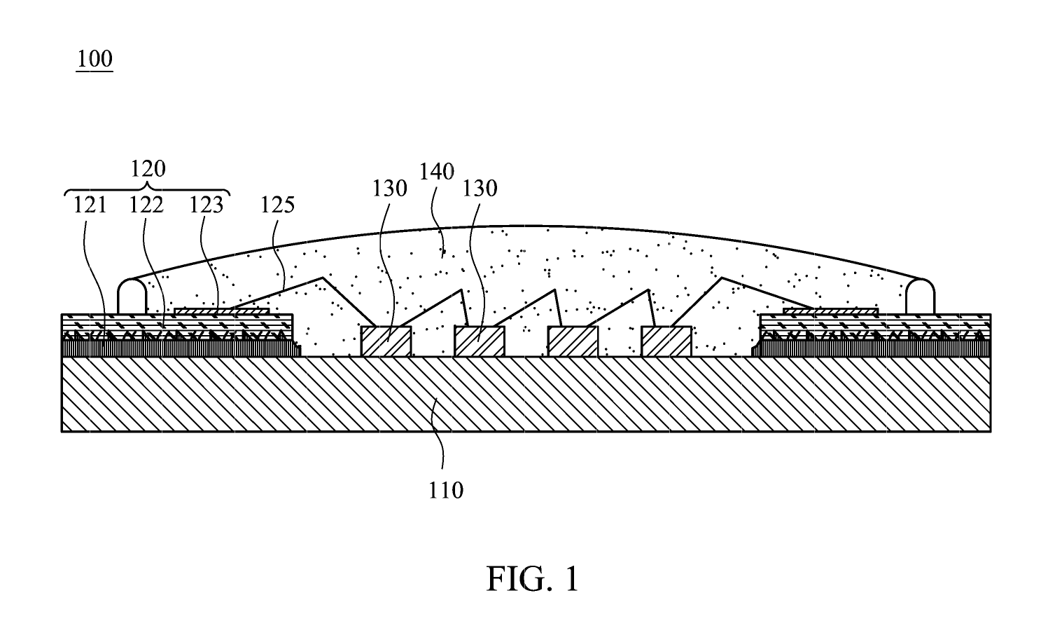

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

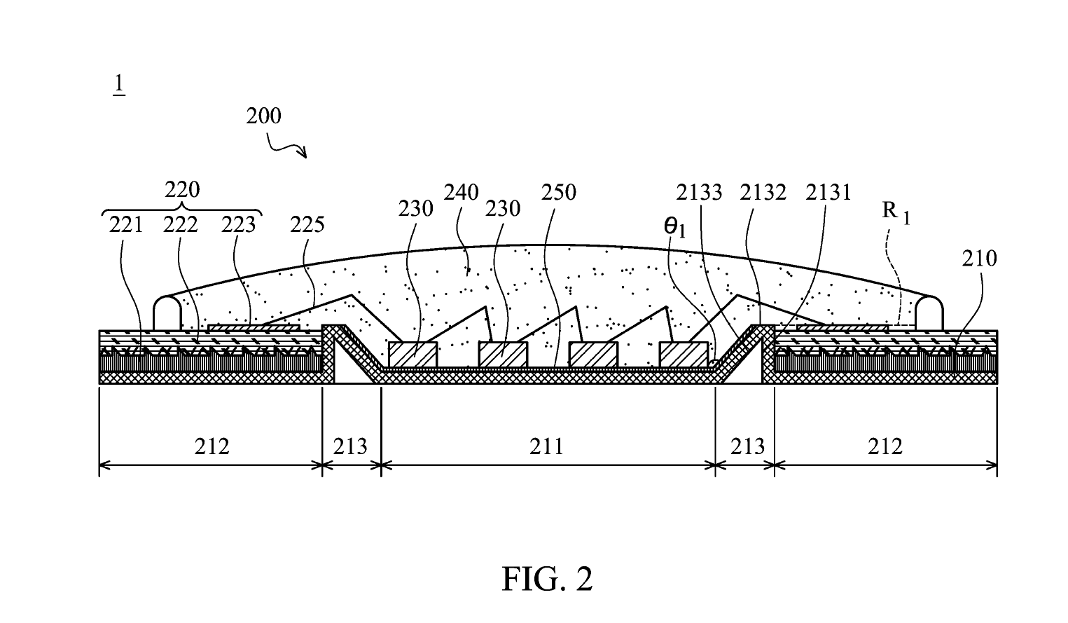

Referring to FIG. 2, a light-emitting element 1 includes one or more than one LED (light-emitting diode) package 200, in accordance with one embodiment of the disclosure. The LED package 200 may be used for illumination, backlighting, or like applications.

The LED package 200 includes a heat dissipation plate 210, a composite structure 220, a number of LED chips 230, an encapsulant 240, and a reflective layer 250. The heat dissipation plate 210 includes a chip bonding area 211, a circuit area 212, and a first dam 213 separating the chip bonding area 211 and the circuit area 212. The first dam 213 has an outer wall 2131 facing the circuit area 212, an inner wall 2133 facing the chip bonding area 211, and a top end 2132 connecting the outer wall 2131 with the inner wall 2133. The outer wall 2131 is perpendicular to the circuit area 212 of the heat dissipation plate 210. An angle θ₁ is formed between the inner wall 2133 and the chip bonding area 211 of the heat dissipation plate 210. The angle θ₁ can be varied according to light extraction efficiency or light-emitting angle. Preferably, the angle θ₁ is greater than 90 degrees and less than 180 degrees.

It should be noted that the heat dissipation plate in the embodiment is made of a metal having high heat dissipation efficiency (e.g., aluminum, or another metal with better heat conductivity), and the first dam 213 of the heat dissipation plate 210 is formed by punching or bending the heat dissipation plate 210. That is, the chip bonding area 211 and the circuit area 212 and the first dam 213 are formed integrally, and the heat dissipation plate 210 has an equal thickness. In one exemplary embodiment, the thickness of the heat dissipation plate 210 ranges from about 0.1 mm to about 1.5 mm to facilitate processing.

The composite structure 220 comprises a pressing layer 221, a dielectric layer 222, and a circuit layer 223 successively stacked on the circuit area 212 of the heat dissipation plate 210. The top end 2132 of the first dam 213 is as high as the surface of the composite structure 220. Namely, the top end 2132 of the first dam 213 and the top surface of the composite structure 220 are located at the horizontal line R₁. In the other non-illustrated embodiment, the top end 2132 of the first dam 213 is higher than the surface of the composite structure 220. Namely, the top end 2132 of the first dam 213 is located at the horizontal line R₁, and the top surface of the composite structure 220 is located below the horizontal line R₁.

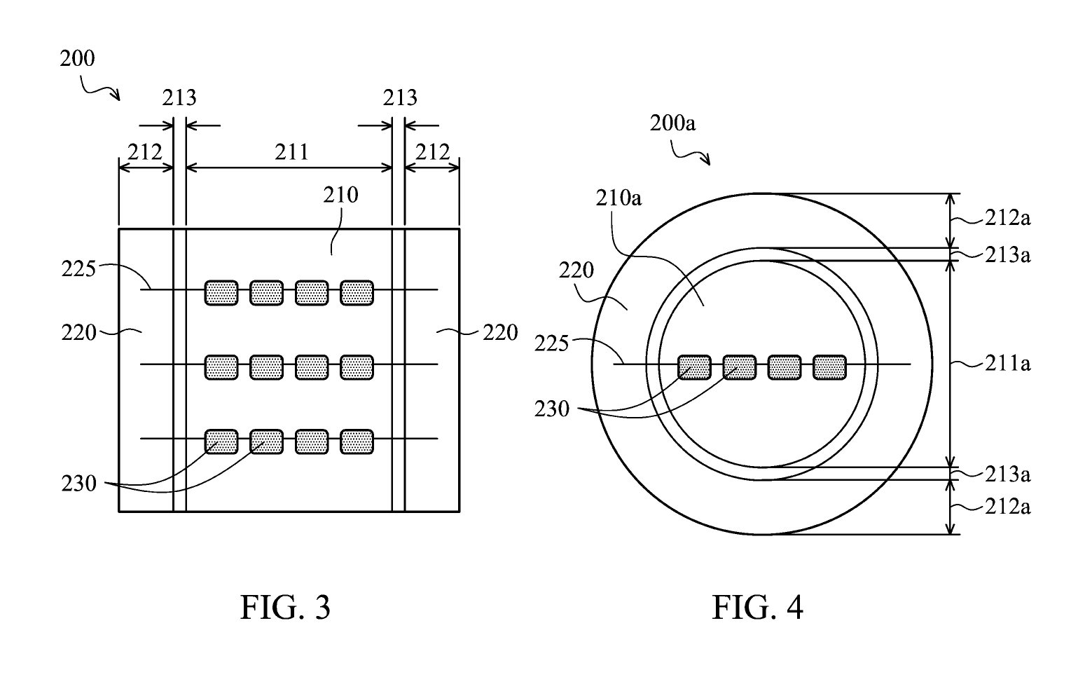

As shown in FIG. 3, the LED chips 230 are arranged at the chip bonding area 211 in a matrix and electrically connected to the circuit layer 223 of the composite structure 220 by gold wire 225. Additionally, as shown in FIG. 2, the LED chips 230 and a portion of the composite structure 220 is covered by the encapsulant 240. The other portion of the composition structure 220 is exposed out of the encapsulant 240 and serves as an external electrode. With such an arrangement, light from the LED chips 230 is blocked from being projected on the composite structure 220 by the first dam 213, such that the degradation of the circuit layer and the pressing adhesive can be prevented, and the lifespan of the LED package 200 is extended.

In the embodiment, in order to increase the light extraction efficiency and reduce the loss of optical energy, the chip bonding area 211 of the heat dissipation plate 210 is applied with the reflective layer 250, and the LED chips 230 are fixed on the reflective layer 250. The reflective layer is made of metallic material having reflective properties or another material having a high reflectivity. It is appreciated that the reflective layer 250 can be omitted, and light from the LED chips 230 can be directly reflected by the surface of the heat dissipation plate 210.

The configuration of the heat dissipation plate 210 should not be limited by the embodiments set above. For example, as shown in FIG. 4, a heat dissipation plate 210a with a circular shape is shown. The heat dissipation plate 210a includes a chip bonding area 211a, a circuit area 212a, and a first dam 213a separating the chip bonding area 211a and the circuit area 212a. The LED chips 230 are positioned in the chip bonding area 211a, and the composite structure 220 is positioned at the circuit area 212a. The first dam 213a completely surrounds the outer side of the chip bonding area 211a so as to block light of the LED chips 230 from emitting to the composite structure 220.

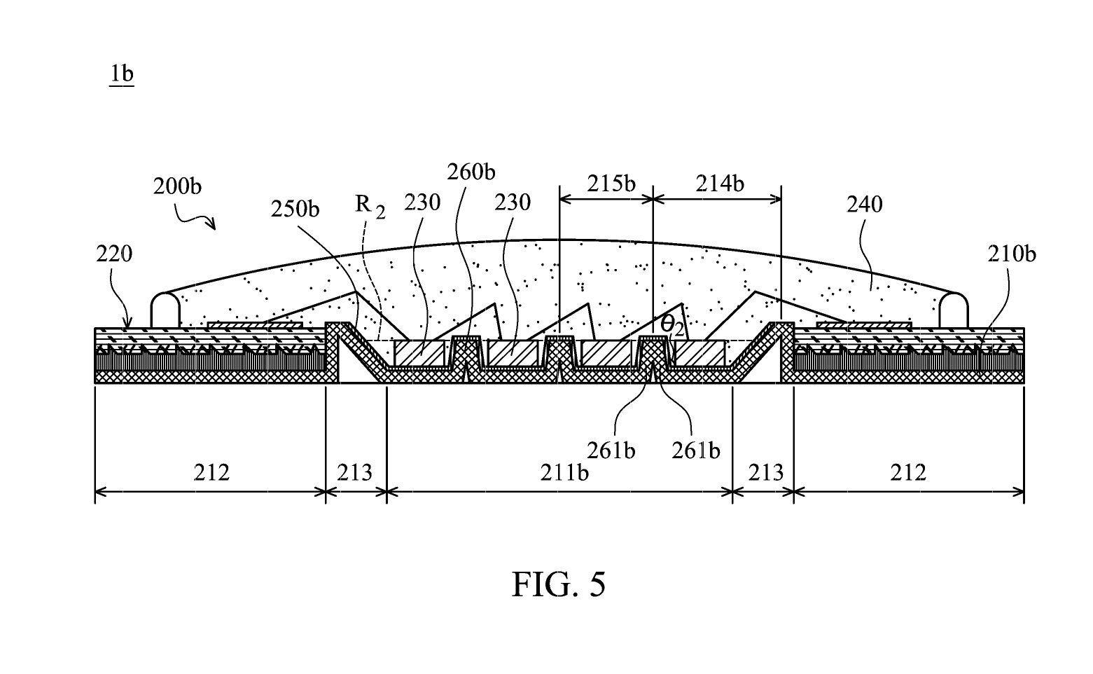

Referring to FIG. 5, a light-emitting element lb of the other embodiment is shown. In FIG. 5, similar elements which are shown in FIG. 2 are provided with the same reference numbers, and the features of similar elements are not reiterated in the interest of brevity. Differences between the light-emitting element 1 and the light-emitting element lb includes the light-emitting element lb including an LED package 200b. A heat dissipation plate 210b of the LED package 200b includes a chip bonding area 211b, and the chip bonding area 211b includes a number of chip bonding sub-areas 214b and 215b. The chip bonding sub-areas 214b and 215b are separated by a second dam 260b. The height of the second dam 260b is less than the height of the first dam 213, and the bottom surface of each of the chip bonding sub-areas 214b and 215b is more depressed than the surface of the top end of each second dam 260b. The LED chips 230 are respectively disposed in each of the chip bonding sub-areas 214b and 215b.

In some embodiments, the heat dissipation plate 210b includes a number of second dams 260b. The chip bonding sub-area 214b is located between the first dam 213 and one of the second dams 260b, and the chip bonding sub-area 215b is located between two of the second dams 260b. Each of the second dams 260b has two side walls 261b respectively facing two of the neighboring LED chips 230. An angle θ₂ is formed between each of the two side walls 261b and the bottom surface of the chip bonding sub-areas 214b and 215b. The angle θ₂ can be varied according to light extraction efficiency or light-emitting angle. Preferably, the angle θ₂ is greater than 90 degrees and less than 180 degrees.

The depth of the each chip bonding sub-area 214b and 215b is equal to the height of each LED chip 230. Namely, the height of each second dam 260b is equal to the height of each LED chip 230. The top end of each second dam 260b and the light emitting surface of each LED chip 230 are located at the horizontal line R2. In the other non-illustrated embodiment, the depth of each of the chip bonding sub-areas 214b and 215b is larger than the height of each LED chip 230. Namely, the height of each second dam 260b is larger than the height of each LED chip 230. The top end of each second dam 260b is located at the horizontal line R2, and the light emitting surface of each LED chip 230 is located below the horizontal line R2. With such an arrangement, the light-absorbing effect of the LED chips 230 is avoided, and the light extraction efficiency of the light-emitting element lb is increased.

It should be note that, as with the first dam 213, the second dams 260b of the heat dissipation plate 210b are formed by punching or bending the heat dissipation plate 210b. That is, the chip bonding area 211, the circuit area 212, the first dam 213, and the second dams 260b are formed integrally, and the heat dissipation plate 210b has an equal thickness. In one exemplary embodiment, the thickness of the heat dissipation plate 210b ranges from about 0.1 mm to about 1.5 mm to facilitate processing.

In the embodiment, in order to increase the light extraction efficiency of the LED package 200b, the surface of the chip bonding area 211b of the heat dissipation plate 210b is applied with the reflective layer 250b, and the LED chips 230 are positioned in the chip bonding sub-areas 214b and 215b where the reflective layer 250b is applied. The reflective layer 250b, for example, is made of metallic material having reflective properties or another material having a high reflectivity. It is appreciated that the reflective layer 250b can be omitted, and light from the LED chips 230 is directly reflected by the surface of the heat dissipation plate 210.

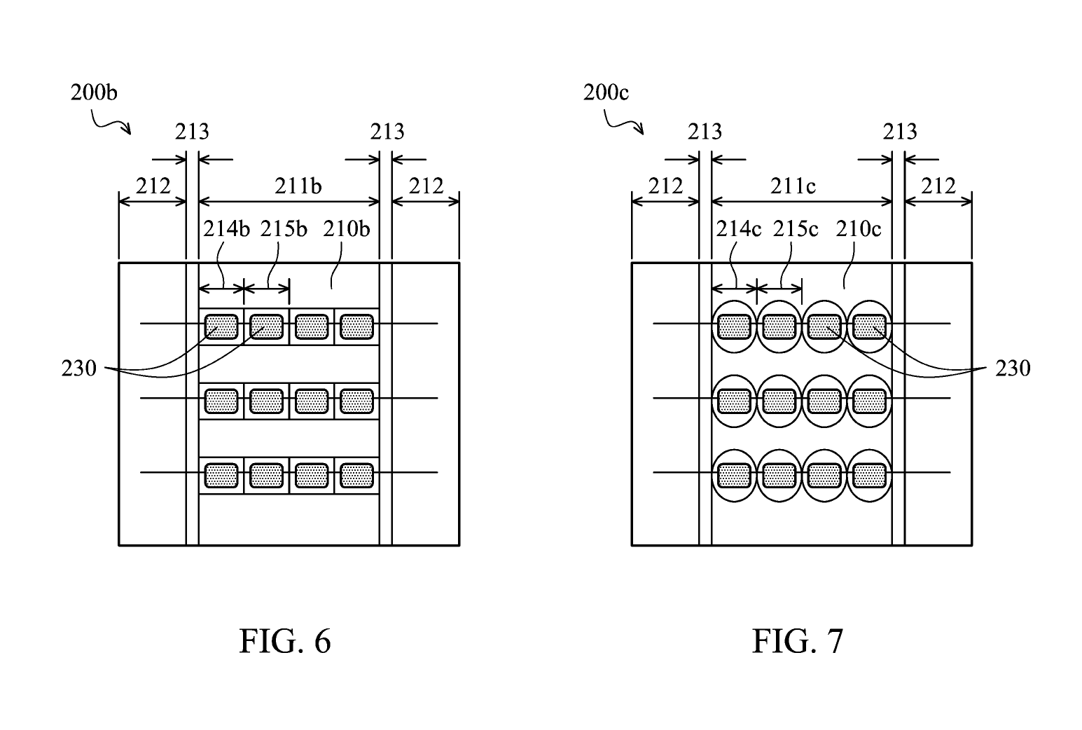

As seen from the top view according to FIG. 6, each of the chip bonding sub-areas 214b and 215b is a rectangular recess; however, it should not be limited thereto. In the other embodiment, as shown in FIG. 7, an LED package 200c includes a number of chip bonding sub-areas 214c and 215c. Each of the chip bonding sub-areas 214c and 215c is a circular recess. The LED chips 230 are positioned in each of the chip bonding sub-areas 214c and 215c.

To avoid degradation of the pressing layer and the dielectric layer caused by high-intensity light, the manufactures typically machine a number of depressed structures on the surface of a metallic substrate with a milling process for accommodating LED chips, such that light from the LED chips can be blocked. However, it is complicated and difficult to implement the milling process, and the flatness and the height of each depressed structure is varied, resulting in a reduction of the light uniformity of the LED package. In addition, the light reflectivity of the surface of each depressed structure will inevitably be decreased in the milling process which results in a reduction of the brightness of the LED package.

However, in the disclosure, the chip bonding area for accommodating the LED chips is formed by a punching or bending process. The flatness and the height of each chip bonding area are substantially identical. Therefore, the light uniformity of the LED package is increased. In addition, a decrease of the light reflectivity of the surface of the chip bonding area will not occur in the punching or bending process, such that the brightness of the LED package can be maintained. Moreover, in cases where the LED package is directly positioned on a heat dissipation base which has high heat-dissipation efficiency, the heat from the LED chips can be readily dissipated, and damage to the LED chips, pressing layer, and dielectric layer can be prevented.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An LED package, comprising:
a heat dissipation plate having a chip bonding area, a circuit area, and a first dam separating the chip bonding area and the circuit area, wherein the first dam is formed by punching or bending the heat dissipation plate;
a composition structure disposed on the heat dissipation plate;
an LED chip disposed in the chip bonding area and electrically connected to the composition structure; and
an encapsulant covering the LED chip.

2. The LED package as claimed in claim 1, wherein the first dam has an outer wall facing the circuit area and an inner wall facing the chip bonding area, wherein the outer wall is perpendicular to the circuit area of the heat dissipation plate, and an angle θ₁ is formed between the inner wall and the chip bonding area of the heat dissipation plate, and the angle θ₁ is greater than 90 degrees and less than 180 degrees.

3. The LED package as claimed in claim 1, wherein the top end of the first dam is as high as the surface of the composition structure.

4. The LED package as claimed in claim 1, comprising a plurality of LED chips disposed in the chip bonding area, wherein each two neighboring LED chips are separated from each other by a second dam.

5. The LED package as claimed in claim 4, wherein the height of the second dam is equal to or larger than the height of the LED chips.

6. The LED package as claimed in claim 5, wherein the second dam is formed by punching or bending a portion of the heat dissipation plate corresponding to the chip bonding area.

7. The LED package as claimed in claim 1, wherein the composition structure comprises a pressing layer, a dielectric layer, and a circuit layer successively stacking on the circuit area of the heat dissipation plate.

8. The LED package as claimed in claim 1, further comprising a reflective layer formed on the surface of the chip bonding area, so that the LED chip is fixed on the reflective layer.

9. The LED package as claimed in claim 1, wherein the heat dissipation plate comprises a metal with high heat dissipation efficiency, and the thickness of the heat dissipation plate ranges from 0.1 mm to 1.5 mm.

10. A light-emitting element comprising the LED package as claimed in claim 1.

11. An LED package, comprising:
a heat dissipation plate having a chip bonding area, a circuit area, and a first dam separating the chip bonding area and the circuit area, wherein the surface of the chip bonding area has a plurality of depressed chip bonding sub-areas formed by punching;
a composition structure disposed on the circuit area;
a plurality of LED chips, wherein each of the LED chips is disposed in one of the depressed chip bonding sub-areas and electrically connected to the composition structure; and
an encapsulant covering the LED chips.

12. The LED package as claimed in claim 11, wherein the first dam has an outer wall facing the circuit area and an inner wall facing the chip bonding area, wherein the outer wall is perpendicular to the circuit area of the heat dissipation plate, and an angle θ₁ is formed between the inner wall and the chip bonding area of the heat dissipation plate, and the angle θ₁ is greater than 90 degrees and less than 180 degrees.

13. The LED package as claimed in claim 11, wherein the top end of the first dam is as high as the surface of the composition structure.

14. The LED package as claimed in claim 11, wherein each of the depressed chip bonding sub-areas is a circular recess or a rectangular recess.

15. The LED package as claimed in claim 14, wherein the depth of each depressed chip bonding sub-area is equal to or larger than the height of each LED chip.

16. The LED package as claimed in claim 14, wherein an angle θ₂ is formed between a side wall of each depressed chip bonding sub-area and the surface of the corresponding depressed chip bonding sub-area, and the angle θ₂ is greater than 90 degrees and less than 180 degrees.

17. The LED package as claimed in claim 11, wherein the composition structure comprises a pressing layer, a dielectric layer, and a circuit layer successively stacking on the circuit area of the heat dissipation plate.

18. The LED package as claimed in claim 11, further comprising a reflective layer formed on the surface of the chip bonding area, so that the LED chip is fixed on the reflective layer.

19. The LED package as claimed in claim 11, wherein the heat dissipation plate comprises a metal with high heat dissipation efficiency, and the thickness of the heat dissipation plate ranges from 0.1 mm to 1.5 mm.

20. A light-emitting element comprising the LED package as claimed in claim 11.
